(19) United States
(12) Patent Application Publication
(10) Pub. No.: US 2009/0108437 A1
(43) Pub. Date: Apr. 30, 2009

(54) WAFER SCALE INTEGRATED THERMAL HEAT SPREADER

(75) Inventor: Brook D. Raymond, Roanoke, VA (US)

Correspondence Address: Tyco Electronics Corporation, Suite 140, 4550 New Linden Hill Road, Wilmington, DE, 19808-2952, US

(73) Assignee: M/A-COM, INC., Lowell, MA (US)

(21) Appl. No.: 11/927,109

(22) Filed: Oct. 29, 2007

(51) Int. Cl. H01L 23/36; H01L 21/304

(52) U.S. Cl. 257/713; 438/113; 257/E23.109; 257/E21.238

(57) ABSTRACT

Various embodiments are directed to providing an electronic device with an integrated thermal heat spreader. In one embodiment, an electronic device may comprise an integrated circuit fabricated on a substrate and a heat spreader integrated with the electronic device after fabrication of the integrated circuit. The heat spreader may comprise one or more layers of composite plating material including solid particles incorporated into a metal plating material. The composite plating material may be patterned to the substrate to define the heat spreader. Other embodiments are described and claimed.

### BACKGROUND

The active circuitry of an integrated circuit (IC) may generate unwanted heat causing increased temperature which can adversely impact the performance and reliability of a chip or die as well as a higher value device or system which incorporates the chip or die. Typically, heat is generated and concentrated in specific regions (active areas) of the die and radiates out and through the substrate and package. Spreading the heat away from these active areas lowers temperature and is useful for improving performance and reliability of electronic devices.

In some cases, metal such as a 2-5 μm thick gold layer can be placed on the back of the die. Such metallization between the device and the package has excellent thermal connectivity but provides very minor lateral heat spreading effect due to the relatively low thickness. Using greater metal thickness, however, raises stresses and may cause bowing due to the significantly different expansion rates between the metal and the substrate resulting in component failure. This stress results in reliability concerns during successive heating and cooling cycles which can result in delamination. Greater metal thickness also poses a significant die separation (dicing) problem especially when the metallization consists of a composite containing particles with hardness approaching or equal to the hardness of the saw blade cutting tool.

It is common practice to attach a heat spreader to an individual die using solder or epoxy to reduce device temperatures by conducting unwanted heat away from the active areas of the device. The heat spreaders are formed to specialized shapes (e.g., heat sink, pedestal, carrier, shim, etc.) related to the device size and must be metalized individually, typically with Nickel then Gold (Ni/Au), to aid in soldering. The solder also must be shaped to the device dimensions, requiring large inventories of various size heat spreaders and solders.

The heat spreader can be formed of a controlled expansion rate material that has a similar Coefficient of Thermal Expansion, a (CTE) to the substrate such as Copper Tungsten (CuW), Copper Molybdenum (CuMo), and Aluminum Silicon Carbide AlSiC. The solders and epoxies, however, typically have relatively low thermal conductivity impeding heat flow. In addition, these solder and epoxy materials such as gold-tin (AuSn) often have high expansion rates compared to the substrate and result in additional undesirable stresses.

The process of die alignment and soldering to the heat spreader is labor intensive and critical due to tight board assembly specifications necessary to control radio frequency (RF) performance variation. A misplaced die results in changes in wirebond lengths which affect RF performance. Moreover, this processing step often is the responsibility of a customer and performed prior to incorporating the die into a larger assembly which can introduce additional uncertainty and reliability issues due to process variations.

The solder assembly of a heat spreader onto a die requires a reducing environment or a vacuum chamber to minimize contamination such as oxidation. Minute contamination can cause voids, cracks, and/or regions where solder fails to contact the die and/or the heat spreader. Trapped gasses found in through-chip via connections also can generate undesirable voids. In addition, rapid heating and cooling necessary to minimize the thermal budget of the device compete with stress levels in the solder due to mismatched cooling rates of the assembly which can result in solder cracks.

Voids and cracks in the solder sharply reduce the thermal conductivity and can lead to device failure. For example, junction temperature (Tj) increases near voids reducing the effective cooling and reliability of the die. Increased die size and wafer thinning also compound void and stress crack issues due to the introduction of additional stresses.

Voids and cracks in the solder are difficult to detect. Typically, each chip must undergo inspection using an X-ray or Acoustic microscopy to verify solder joint integrity and ensure that there are no voids or cracks. For devices designed to utilize performance advantages of a heat spreader, is not possible to directly assess the ultimate device performance until the assembly steps are complete.

The assembly cost (e.g., capitalization, materials, labor, inventory, facilities, and quality) of die attach is a significant portion of the overall product cost. Devices not meeting performance requirements and not adequately screened pose significant business risks resulting from the return of defective products and/or the failure of a high value device or system which incorporates a defective chip.

### SUMMARY

Various embodiments are directed to providing an electronic device with an integrated thermal heat spreader. In one embodiment, an electronic device may comprise an integrated circuit fabricated on a substrate and a heat spreader integrated with the electronic device after fabrication of the integrated circuit. The heat spreader may comprise one or more layers of composite plating material including solid particles incorporated into a metal plating material. The composite plating material may be patterned to the substrate to define the heat spreader.

In one embodiment, an apparatus may comprise a plurality of dies fabricated on a single wafer and a plurality of photoresist masks defining a patterning for depositing a controlled expansion rate composite plating metallization to fabricate a plurality of heat spreaders corresponding to the dies.

In one embodiment, a method may comprise defining patterning on a wafer for a plurality of heat spreaders, depositing controlled expansion rate composite plating metallization according to the patterning, and dicing the wafer to form a plurality of heat spreaders.

### BRIEF DESCRIPTION OF THE DRAWINGS

FIG. 1 illustrates one embodiment of an electronic device.

FIG. 2 illustrates one embodiment of a wafer scale apparatus.

FIG. 3 illustrates one embodiment of a heat spreader.

FIG. 4 illustrates one embodiment of a wafer.

FIG. 5 illustrates one embodiment of a wafer scale process flow.

### DETAILED DESCRIPTION

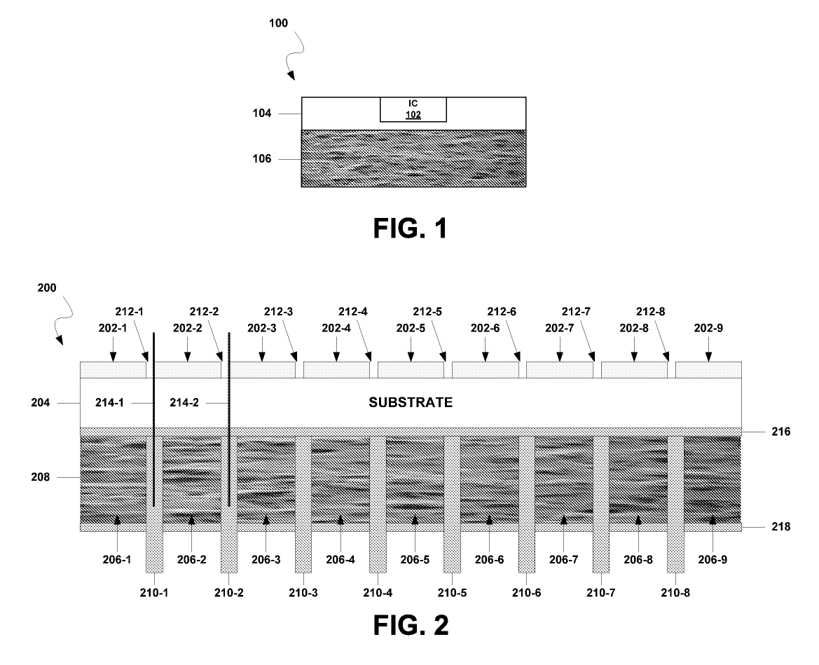

FIG. 1 illustrates one embodiment of an electronic device 100. As shown, the electronic device 100 may comprise active circuitry such as an integrated circuit (IC) 102 fabricated on a substrate 104. The electronic device 100 may comprise, for example, a power device, die, chip, unit, and/or other type of device in accordance with the described embodiments.

The IC 102 may comprise a power IC such as a monolithic microwave integrated circuit (MMIC). The IC 102 may comprise and/or be implemented by various electronic and/or microelectronic components fabricated on the substrate 104 and arranged in a particular network configuration in accordance with desired design and/or performance requirements. Exemplary components may include transistors such as a field-effect transistor (FET) (e.g., MOSFET, MESFET, PHEMT, etc.), diodes such as a light-emitting diode (LED) and/or laser diode, resistors, capacitors, inductors, and/or other types of suitable electronic and/or microelectronic components in accordance with the described embodiments.

The substrate 104 may comprise a material such as Gallium Arsenide (GaAs), Gallium Nitride (GaN), Silicon (Si), Silicon Carbide (SiC), Indium Phosphide (InP), Germanium (Ge), Sapphire, and/or any other suitable substrate material in accordance with the described embodiments. In an exemplary embodiment, the substrate 104 comprises GaAs. It is noted that for GaAs, thermal conductivity, k=54 W/m-K and α=6.5 ppm/° C., both at measured at room temperature.

When active, certain components (e.g., FET gate) of the IC 102 may generate unwanted heat causing increased temperature concentrated in specific regions (active areas) of the electronic device 100. As shown, the electronic device 100 comprises a heat spreader 106 designed to conduct unwanted heat away from the active areas of the electronic device 100. In general, the heat spreader 106 is formed of a material having excellent thermal conductivity and sufficient thickness to cause lateral diffusion of heat necessary to appreciably reduce the operating device temperature.

In various embodiments, the material forming the heat spreader 106 may have significantly higher thermal conductivity (e.g., 2× or better) than that of conventional heat spreading material (e.g., CuW, thermal conductivity, k=190 W/m-K). In some implementations, the heat spreader 106 may comprise 25-1000 μm of high thermal conductivity material. For example, by appropriately controlling the thermal expansion rate of the heat spreader 106, the thickness restrictions (e.g., 2-5 μm thick) imparted for conventional materials such as Au, Cu, Ag, Al can be lifted.

The heat spreader 106 may comprise a composite plating material including solid particles incorporated into a plating metal material to form a heat spreading material. The solid particles may comprise, for example, Diamond, Silicon Carbide (SiC), Beryllium (Be), Beryllium oxide (BeO), Carbon Fiber, Carbon Nanotube, and/or others in accordance with the described embodiments. With asymmetric materials having a different coefficient of thermal expansion or thermal conductivity depending on the orientation, it is desired to substantially control the particle orientation (e.g., parallel X, Y versus perpendicular Z) with respect to the substrate 104 to achieve desired results.

The metal plating material may comprise, for example, Copper (Cu), Aluminum (Al), Gold (Au), Silver (Ag), Tin (Sn), Nickel (Ni), Chromium (Cr), Tungsten (W), Molybdenum (Mo), appropriate alloy, and others in accordance with the described embodiments. In one exemplary embodiment, the heat spreader 106 comprises Cu/Diamond (Cu—C) composite plating material, where C denotes Diamond-like or high-pressure Carbon.

In various embodiments, the composite plating material forming the heat spreader 106 has a controlled expansion rate. The expansion rate of the composite plating material forming the heat spreader 106 may be controlled by incorporating solid particles (e.g., Diamond, SiC, Be, BeO, Carbon Fiber, Carbon Nanotube, etc.) having a relatively low expansion rate into a plating bath of relatively high expansion rate plating material (e.g., Cu, Al, Au, Ag, Sn, Ni, Cr, W, Mo, alloys, etc.). The volume ratio of particles to metal plating material and/or other factors may be controlled to form a heat spreading material with the appropriate or desired net medium expansion rate.

In some cases, the particle content of the composite plating material may be controlled such that the CTE of the composite material forming the heat spreader 106 substantially matches the CTE of the substrate 104 (e.g., GaAs, GaN, Si, SiC, InP, Ge, Sapphire, etc.). It is noted that the particle content controls the expansion match. For example, higher Diamond content results in a lower expansion rate. In various implementations, Cu—C composite plating material may have 30%-65% Diamond content, for example.

In one embodiment, for example, the substrate 104 may comprise GaAs having an α=6.5 ppm/° C., and the heat spreader 106 may comprise 65% Cu—C having an α≈6.5 ppm/° C. In this embodiment, the Cu—C composite plating material forming the heat spreader 106 also may have very high thermal conductivity (e.g., 400<k<1400 W/m-K).

In addition to controlling the CTE of the composite film by controlling the particle composition, layers of localized deposits of various material which have lower thermal coefficient of expansion may be utilized to reduce the overall coefficient of thermal expansion of the integrated heat spreader beyond what is practical for Cu—C. This may be especially desirable for substrates with low CTE.

In various embodiments, the heat spreader 106 may comprise a multi-layer integrated heat spreader with lower CTE. For instance, to meet requirements for lower CTE rates than practical or achievable with Cu—C, a multi-layer integrated thermal heat spreader may be grown using one or more layers of Cr—C. Since Chromium has a significantly lower coefficient of expansion than Copper, layering can produce integrated heat spreaders with even lower expansion. The layers may comprise, for example:

Au
Ni
Cu—C
Cr—C
Cu—C
Cr—C
Cu—C
Barrier
Substrate

Moreover, the use of lower coefficient of thermal expansion material or composite may be used in conjunction with selective deposition techniques to deposit this material in specific regions of the device only. These regions may be more susceptible to temperature changes due to the proximity to heat sources, or may be within thermal mesa cavities which may require more specialized expansion rate controlled material.

As shown, the heat spreader 106 is integrated with the electronic device 100. In various embodiments, the heat spreader 106 may be integrated during fabrication of the electronic device 100. For example, the heat spreader 106 may comprise one or more layers of composite plating material (e.g., Cu—C) deposited to the backside of the substrate 104 after a functional IC 102 has been fabricated and/or has undergone testing. In some embodiments, the electronic device 100 and/or IC 102 may be implemented by one of several identical dies fabricated on a single wafer of semiconductor substrate, and the heat spreader 106 may be integrated during the fabrication process when the dies are still connected on the wafer.

It is noted that integrating the heat spreader 106 into the electronic device 100 may eliminate the need for a customer to attach specialized heat spreading properties to the electronic device 100 prior to incorporation into a larger assembly. As a result, customers are relieved from the responsibility of performing certain labor intensive and critical processing steps. In addition, integrating the heat spreader 106 into the electronic device 100 will standardize processing and improve reliability. Moreover, through appropriate selection of certain materials to form the heat spreader 106, overall production cost can be lowered through a reduction in material and labor costs.

In various embodiments, the heat spreader 106 may be plated directly to the substrate 104 without the need and/or use of solder or epoxy. In general, the heat spreader 106 may comprise one or more layers of electrochemically or electrolessly plated composite material. It is noted that eliminating the need and/or use of solder by plating the heat spreader 106 directly to the electronic device 100 eliminates the possibility of solder voids and cracks as well as the need to subject the electronic device 100 to X-ray or Acoustic microscopy inspection to verify solder joint integrity.

It also is noted that, in some embodiments, the electronic device 100 may comprise an initial adhesion, barrier and/or seed metalization layer(s) and/or a final metalization layer to prevent problems such as diffusion, peeling, corrosion and oxidation. Exemplary materials may include, for example, Titanium, Chromium, Gold Germanium, Palladium, Gold, Copper, Tin, Lead, Silver, Indium, Tungsten, Nickel, NiCr, Tantalum, Hafnium, Niobium, Zirconium, Vanadium, Tantalum Nitride, Indium Oxide, Copper Silicide, Titanium Nitride, and others in accordance with the described embodiments. In such embodiments, the adhesion, barrier and/or seed metalization layer may be formed on the bottom surface of the substrate 104, and the composite plating material forming the heat spreader 106 may be plated directly to the barrier or seed metallization layer. In some cases, it is required to insert an adhesion layer such as Ti or Cr, for example. The final metalization layer may be applied to the electronic device 100 below the composite plating material forming the heat spreader 106.

In some embodiments, the substrate 104 (e.g., GaAs, GaN, Si, SiC, InP, Ge, Sapphire, etc.) or wafer may be thinned to improve thermal conductivity by decreasing the separation between the heat spreader 106 and the low thermal conductivity substrate 104. It is noted that for very thin substrates (e.g., <2 mil), mechanical integrity considerations impose limits to the minimum thickness. In addition, thinning the substrate 104 may limit performance benefits in some cases where the electrical conductivity of the heat spreader 106 imparts higher transmission line losses in the electronic device 100.

To offset these trade-offs, the substrate 104 may comprise thermal mesas and/or through-wafer vias made by photoresist masking and local thinning of key regions under the IC 102 to device to gain additional thermal performance. It is noted that lack of adequate expansion rate control within thermal mesas and/or through-wafer vias can cause mechanical failure after temperature fluctuation. Accordingly, to realize thermal mesas and/or through-wafer vias which are reliable and effective, heat spreader 106 may comprise various composite films layered in succession to address specific thermal performance considerations. For example, composite plating material within thermal mesas and through-wafer vias may require a slightly lower expansion rate material than the substrate 104, while overall a slightly higher expansion rate composite material may be desired. To accomplish this, a multiple layering technique can be used, starting with deposition of a low expansion rate composite film and followed by deposition of a higher expansion rate composite film.

In addition, a smooth, flat and/or machinable upper surface may be required which may not have optimum overall expansion rate. By depositing a final layer of material without particles or using machinable particulate, subsequent grinding or polishing processes can result in flat and/or smooth finishes if so desired. For critical expansion rate control applications, a feedback loop could be established thereby adjusting the upper layers based on intermediately measured expansion rate values to form net optimal properties.

As described above, in some embodiments, the electronic device 100 and/or IC 102 may be implemented by one of a plurality (e.g., identical) of dies fabricated on a single wafer of semiconductor substrate. In such embodiments, the heat spreader 106 may comprise one of a plurality (e.g., identical) of integrated heat spreaders corresponding to the dies. After the corresponding heat spreaders are integrated while the dies are still attached to the wafer, the wafer may be diced to form a plurality of electronic devices (e.g., 100), each including an IC (e.g., IC 102) and an integrated heat spreader (e.g., heat spreader 106).

It is noted that suitable composite plating metallizations (e.g., Cu—C) may involve hard and chemically resistant particles (e.g., Diamond), inapt for subsequent matching or sizing. Accordingly, systems and techniques are needed for depositing a thick controlled expansion rate composite plating material useful for heat spreading applications on a wafer (e.g., array, panel, substrate) and subsequently separating the wafer into individual electronic devices (e.g., dies, chips, units, pieces).

FIG. 2 illustrates one embodiment of a wafer scale apparatus 200 used to form a plurality of electronic devices each comprising an integrated heat spreader. In this embodiment, the wafer scale apparatus 200 comprises dies 202-1 through 202-9 fabricated on a single wafer 204. As shown, the wafer scale apparatus 200 comprises corresponding heat spreaders 206-1 through 206-9 for the dies 202-1 through 202-9 fabricated on the wafer 204. It can be appreciated that the wafer scale apparatus 200 may comprise or implement a greater or fewer number of dies and corresponding heat spreaders in accordance with the described embodiments.

In some embodiments, each of the dies 202-1 through 202-9 may comprise an identical IC (e.g., IC 102) such as a power IC or MMIC fabricated on the wafer 204. The wafer 204 may comprise a substrate such as GaAs, GaN, Si, SiC, InP, Ge, Sapphire, and/or any other suitable substrate material in accordance with the described embodiments. In an exemplary embodiment, the wafer 204 comprises a GaAs substrate (k=54 W/m-K and α=6.5 ppm/° C.).

In various implementations, heat spreading capability is integrated into the wafer 204 by depositing composite plating metallization 208 during the fabrication process while the dies 202-1 through 202-9 are connected on the wafer 204. The composite plating metallization 208 may comprise one or more layers of composite plating material having excellent thermal conductivity and sufficient thickness to cause lateral diffusion of heat necessary to appreciably reduce the operating device temperature.

In some implementations, the composite plating metallization 208 may comprise thick (e.g., 25-1000μ) high thermal conductivity material (e.g., 400<k<1400 W/m-K). The composite plating metallization 208 may comprise a composite plating material including solid particles (e.g., Diamond, SiC, Be, BeO, Carbon fiber, Carbon Nanotube, etc.) incorporated into a plating metal (e.g., Cu, Al, Au, Ag, Sn, Ni, Cr, W, Mo, alloys, etc.) The composite plating metallization 208 may have a controlled expansion rate such that the CTE of the composite material forming the composite plating metallization 208 substantially matches the CTE of the wafer 204 (e.g., GaAs, GaN, Si, InP, etc.). In one exemplary embodiment, the wafer 204 comprises a GaAs substrate (α=6.5) and the composite plating metallization 208 comprises Cu—C composite plating material (e.g., 65% Cu—C) having a α≈6.5.

In various embodiments, the wafer scale apparatus 200 defines a patterning for the composite plating metallization 208. In general, the patterning results in deposition of the composite plating metallization 208 specific to desired locations. By depositing the composite plating metallization 208 according to the defined patterning, the plurality of heat spreaders 206-1 through 206-9 may be integrated into the back of the wafer 204 at the same time.

The composite plating metallization 208 may be electrochemically or electrolessly plated material patterned using thick (e.g., ≈4 mils) photoresist masks 210-1 through 210-8. The photoresist masks 210-1 through 210-8 may use photoresist such as negative tone, electrophoretic, spin-on, spray, dry-film, screen printed, pattern printed, and so forth and/or or any type of suitable masking material to mask the composite plating metallization 208 in selected regions. In various implementations, utilizing photoresist masks 210-1 through 210-8 results in the composite plating metallization layer 208 being discontinuous between dies 202-1 through 202-9 and/or within one or more of heat spreaders 206-1 through 206-9.

In some embodiments, the photoresist masks 210-1 through 210-8 mask the composite plating metallization 208 to facilitate subsequent separation of the dies 202-1 through 202-9 and the corresponding integrated heat spreaders 206-1 through 206-9. As shown, the use of photoresist masks 210-1 through 210-8 result in the deposition of a discontinuous composite plating metallization 208 which defines backside saw streets between dies 202-1 through 202-9. The masks 210-1 through 210-8 eliminate the need to cut through the integrated heat spreaders 206-1 through 206-9.

In this embodiment, a plurality of dicing streets 212-1 through 212-8 may be defined between dies 202-1 through 202-9 using thin (e.g., ≈1-12μ) photoresist masks to facilitate subsequent dicing. As shown, the backside saw streets defined by the photoresist masks 210-1 and 210-2 may align with the dicing streets 212-1 and 212-2 to facilitate dicing and separation of the dies 202-1 and 202-2 and the integrated heat spreaders 206-1 and 206-2 after depositing composite plating metallization 208.

During the dicing of the wafer 204, a first saw cut 214-1 may be made through dicing street 212-1 and the backside saw street defined by photoresist mask 210-1. A second saw cut 214-2 may be made through dicing street 212-2 and the backside saw street defined by the photoresist mask 210-2. When diced, each of the dies 202-1 and 202-2 including corresponding integrated heat spreaders 206-1 and 206-2 can be singulated without altering the composite metalization layer 208.

It is noted that by utilizing photoresist masks 210-1 through 210-8 the composite plating metallization layer 208 is discontinuous. Therefore, any stresses formed during the manufacturing from intentional or unintentional mismatch in expansion rates between the wafer 204 and the composite metalization 208 are restricted in magnitude by the size of the device. By patterning in small discrete sections, substrate bow is prevented facilitating subsequent process steps such as coating or testing.

In some cases, the composite plating metallization 208 may be patterned within the heat spreaders 206-1 through 206-9 to concentrate heat spreading material for active areas of a particular die or features that may be subjected to differing electrical potential. These features are useful for directly attaching active devices such as laser and flip chips to electrically active assemblies.

In some cases, the composite plating metallization 208 may be thicker than 4 mils. In addition, photoresist masks and composite plating may be iteratively layered to achieve a composite plating thickness necessary for a particular application, each layer using a practical single optimized masking thickness.

In various embodiments, the wafer 204 may be thinned to improve thermal connectivity by decreasing the separation between the composite plating metallization 208 and the low thermal connectivity wafer 204. The wafer 204 may comprise thermal mesas and through-wafer vias, and the composite plating metallization 208 may comprise various composite films layered in succession to address specific thermal performance considerations for the thermal mesas and through-wafer vias. For example, a multiple layering technique can be used to deposit composite plating metallization 208, starting with deposition of a high particle content composite film and followed by deposition of a relatively lower particle content composite film.

As shown, the wafer scale apparatus 200 also comprises a barrier metallization layer 216 above the discontinuous composite plating metallization 208 and a final metallization layer 218 below the discontinuous composite plating metallization 208. The barrier metallization layer 216 and the final metalization layer 218 may prevent problems such as diffusion, peeling, corrosion and oxidation. In this embodiment, the barrier metalization layer may be formed on the bottom surface of the wafer 204. The discontinuous composite plating metallization 208 forming the heat spreaders 206-1 through 206-9 may plated directly to the barrier metallization layer 216 in accordance with the defined patterning. In some cases, it is required to insert an adhesion layer such as Ti or Cr, for example. The final metalization layer 218 is applied below the discontinuous composite plating metallization 208 forming the heat spreaders 206-1 through 206-9.

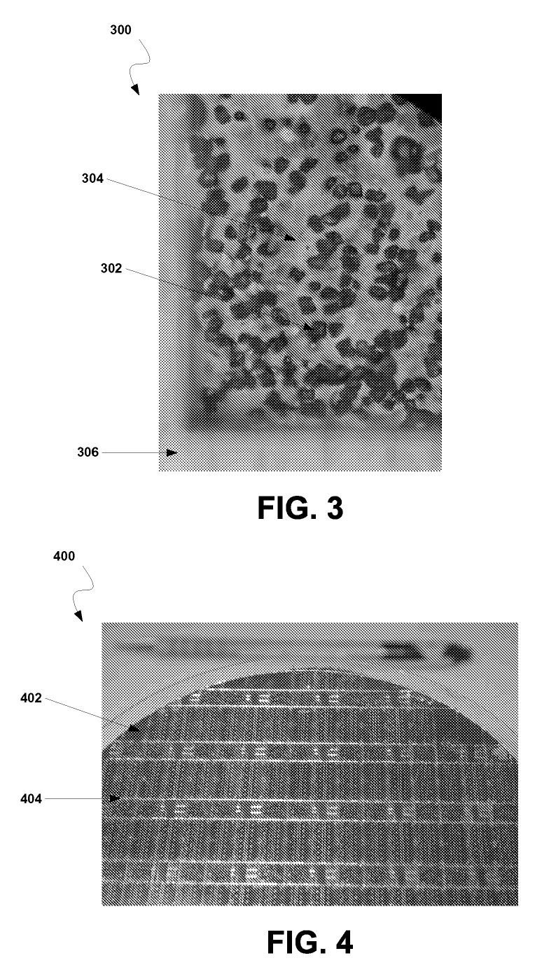

FIG. 3 illustrates one embodiment of a heat spreader 300. As shown, the heat spreader 300 may comprise a composite plating material (e.g., Cu—C) including solid particles 302 (e.g., Diamond) incorporated into a plating metal material 304 (e.g., Cu). The heat spreader 300 also comprises a backside saw street 306 defined by photoresist patterning to facilitate dicing without altering the composite plating material.

In this embodiment, the composite plating material may having excellent thermal conductivity and sufficient thickness to cause lateral diffusion of heat. The heat spreader 300 may comprise thick (e.g., 25-1000 p) high thermal conductivity material (e.g., 400<k<1400 W/m-K) having a controlled expansion rate. The particle (e.g., Diamond) content may be controlled such that the CTE of the composite plating material forming the heat spreader 300 substantially matches the CTE of a substrate (e.g., GaAs, GaN, Si, InP, etc.). In one exemplary embodiment, the heat spreader 300 comprises Cu—C composite plating material (e.g., 65% Cu—C) having a α≈6.5 which substantially matches a GaAs substrate (α=6.5).

FIG. 4 illustrates one embodiment of a wafer 400. As shown, the wafer 400 may comprise a composite plating metallization (e.g., Cu—C) 402 including solid particles (e.g., Diamond) incorporated into a plating metal material (e.g., Cu). The wafer 400 also comprises a backside saw street 404 defined in accordance with photo resist patterning to facility dicing without altering the composite plating metallization 402. It is noted that the wafer 400 may be thinned and may comprise thermal mesas and/or through-wafer vias.

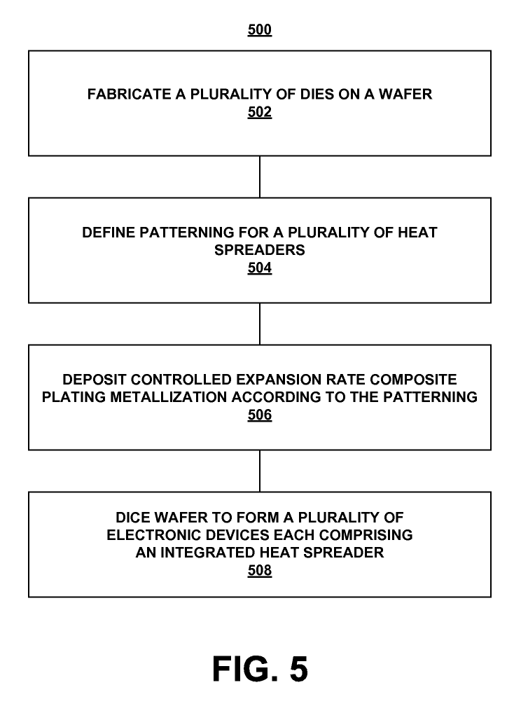

FIG. 5 illustrates one embodiment of a wafer scale process flow 500. In various embodiments, wafer scale process flow 502 may comprise fabricating a plurality of dies on a wafer (block 502), defining patterning on the wafer for a plurality of heat spreaders (block 504), depositing controlled expansion rate composite plating metallization according to the patterning (block 506), and dicing the wafer to form a plurality of electronic devices each comprising an integrated heat spreader (block 508).

In various embodiments, wafer scale process flow 500 may comprise additional processing operations such as mounting the wafer, testing active circuitry of the dies, backside thinning of the wafer, sputter seed metallization, barrier metallization, final metallization, evaporation (e.g., Ti/Pd/Au), demounting the wafer, testing, and picking.

It is noted that the wafer scale process flow 500 eliminates the need for a customer to attach specialized heat spreading properties to an electronic device prior to incorporation into a larger assembly. As a result, customers are relieved from the responsibility of performing certain labor intensive and critical processing steps. In addition, the wafer scale process flow 500 standardizes processing and improves reliability. Moreover, through appropriate selection of certain materials to form the heat spreaders, overall production cost can be lowered through a reduction in material and labor costs.

It also is noted that the wafer scale process flow 500 eliminates the need and/or use of solder and the possibility of solder voids and cracks. As a result, reliability is improved and product cycle time is reduced by eliminating labor and time consuming processes such as ordering and cutting specialized heat sinks and solder, aligning the die and heat spreader during soldering, reflow processing, solder inspection, and other solder assembly steps.

It is further noted that, in some embodiments, individual heat spreaders may be fabricated absent electronic devices by choosing a suitable substrate. Additionally, the application of an integrated heat spreader may not eliminate the need or desire to use an additional soldered or epoxy attached heat spreader. Rather, the integrated heat spreader may be the first level of heat sink and may be combined with another external heat spreader.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

It is also worthy to note that any reference to “various embodiments,” “some embodiments,” “one embodiment,” or “an embodiment” means that a particular feature, structure, or characteristic described in connection with the embodiment is included in at least one embodiment. Thus, appearances of the phrases “in various embodiments,” “in some embodiments,” “in one embodiment,” or “in an embodiment” in places throughout the specification are not necessarily all referring to the same embodiment. Furthermore, the particular features, structures or characteristics may be combined in any suitable manner in one or more embodiments.

While certain features of the embodiments have been illustrated as described above, many modifications, substitutions, changes and equivalents will now occur to those skilled in the art. It is therefore to be understood that the appended claims are intended to cover all such modifications and changes as fall within the true spirit of the embodiments.

1. An electronic device comprising:
an integrated circuit fabricated on a substrate; and
a heat spreader integrated with the electronic device after fabrication of the integrated circuit, the heat spreader comprising one or more layers of composite plating material including solid particles incorporated into a metal plating material, the composite plating material patterned to the substrate to define the heat spreader.

2. The electronic device of claim 1, the heat spreader having a controlled expansion rate wherein a coefficient of thermal expansion (CTE) of the composite plating material substantially matches a CTE of the substrate.

3. The electronic device of claim 2, the heat spreader comprising multiple layers of different composite plating materials, the multiple layers providing an average CTE that substantially matches the CTE of the substrate.

4. The electronic device of claim 1, the composite plating material deposited in selected regions of the substrate.

5. The electronic device of claim 4, the selected regions corresponding to one or more of active areas of the electronic device, thermal mesas, and through-wafer vias.

6. The electronic device of claim 1, the solid particles comprising at least one of Diamond, Silicon Carbide (SiC), Beryllium (Be), Beryllium oxide (BeO), Carbon fiber, and Carbon Nanotube.

7. The electronic device of claim 1, the metal plating material comprising at least one of Copper (Cu), Aluminum (Al), Gold (Au), Silver (Ag), Tin (Sn), Nickel (Ni), Chromium (Cr), Tungsten (W), Molybdenum (Mo), and an alloy.

8. An apparatus comprising:
a plurality of dies fabricated on a single wafer; and
a plurality of photoresist masks defining a patterning for depositing a controlled expansion rate composite plating metallization to fabricate a plurality of heat spreaders corresponding to the dies.

9. The apparatus of claim 8, the plurality of photoresist masks defining saw streets between heat spreaders.

10. The apparatus of claim 8, the plurality of photoresist masks defining patterning within one or more heat spreaders.

11. The apparatus of claim 8, wherein a coefficient of thermal expansion (CTE) of the composite plating metallization substantially matches a CTE of the wafer.

12. The apparatus of claim 11, the composite plating metallization comprising multiple layers of different composite plating materials, the multiple layers providing an average CTE that substantially matches the CTE of the substrate.

13. The apparatus of claim 8, the composite plating metallization deposited in selected regions of the wafer.

14. The apparatus of claim 13, the selected regions corresponding to one or more of active areas of the dies, thermal mesas, and through-wafer vias.

15. The apparatus of claim 8, the composite plating metallization including solid particles comprising at least one of Diamond, Silicon Carbide (SiC), Beryllium (Be), Beryllium Oxide (BeO), Carbon Fiber, and Carbon Nanotube.

16. The apparatus of claim 8, the composite plating metallization including metal plating material comprising at least one of Copper (Cu), Aluminum (Al), Gold (Au), Silver (Ag), Tin (Sn), Nickel (Ni), Chromium (Cr), Tungsten (W), Molybdenum (Mo), and an alloy.

17. A method comprising:
defining patterning on a wafer for a plurality of heat spreaders;
depositing controlled expansion rate composite plating metallization according to the patterning; and
dicing the wafer to form a plurality of heat spreaders.

18. The method of claim 17, further comprising fabricating a plurality of dies on the wafer.

19. The method of claim 17, further comprising defining a saw street between heat spreaders.

20. The method of claim 17, further comprising defining patterning within one or more heat spreaders.

21. The method of claim 17, further comprising layering composite films to control the expansion rate.

22. The method of claim 21, the composite films comprising different composite plating materials providing an average CTE that substantially matches the CTE of the substrate.

23. The method of claim 17, further comprising depositing the composite plating metallization in selected regions corresponding to one or more of active areas of the electronic device, thermal mesas, and through-wafer vias.

24. The method of claim 17, the composite plating metallization including solid comprising at least one of Diamond, Silicon Carbide (SiC), Beryllium (Be), Beryllium Oxide (BeO), Carbon Fiber, and Carbon Nanotube.

25. The method of claim 17, the composite plating metallization including metal plating material comprising at least one of Copper (Cu), Aluminum (Al), Gold (Au), Silver (Ag), Tin (Sn), Nickel (Ni), Chromium (Cr), Tungsten (W), Molybdenum (Mo), and an alloy.
